(19) United States
(12) Patent Application Publication
(10) Pub. No.: US 2011/0220494 A1
(43) Pub. Date: Sep. 15, 2011

(54) METHODS AND APPARATUS FOR MAGNETRON METALLIZATION FOR SEMICONDUCTOR FABRICATION

(76) Inventor: PEIJUN DING, SARATOGA, CA (US)

(21) Appl. No.: 12/722,519

(22) Filed: Mar. 11, 2010

(51) Int. Cl. C23C 14/34

(52) U.S. Cl. 204/298.17; 204/298.16

(57) ABSTRACT

Disclosed is magnetron based metallization processing apparatuses. The apparatus comprises a magnetron which comprises at least one pole piece that is not a permanent magnet at least before the at least one pole piece is assembled in the magnetron assembly. The balance or unbalance ratio of magnetic strength between inner and outer pole pieces may be adjusted by a gap between inner or outer pole pieces and mounting plate. The apparatus may comprise a second magnet assembly that is used to modify the electromagnetic field created by the magnetron assembly for fabricating a semiconductor device. The second magnet assembly comprises electromagnet(s), permanent magnet(s), or ferrous materials. The apparatus may further comprise either DC, pulsed, or RF power supply for charging a sputtering target. The apparatus may comprise a plenum that is used to control the thermal behavior of the sputtering target and is separated from the magnetron assembly.

### BACKGROUND

Physical-vapor deposition (PVD) of metals has been known as one of the most common methods for metallization for semiconductor device fabrication. Conventional methods for physical-vapor deposition comprises evaporation, e-beam evaporation, plasma spray deposition, and sputtering. Metals and metal compounds such as Ti, Al, Cu, TiN, Ni, Co, W, WN, Ta, and TaN may be deposited by PVD. Metal film deposition occurs when a source material is heated above its melting point or sputtered off from the target in an evacuated chamber. During this process, the evaporated or sputtered atoms travel at relatively high velocity in straight-line trajectories onto the semiconductor substrate such as a single crystalline silicon wafer. Due to the ever increasingly complex devices such as high density memory chips and complex logic devices, the modern integrated circuits often require additional metallization by depositing over the previous metallized interconnects another level of dielectric and repeating of etching vias through the dielectric, filling the vias, overlaying the added dielectric layer with metal, and defining the metal above the added dielectric as an additional wiring layer. It is common for modern logic devices, for example, to have five or more levels of metallization.

During the metallization process, a sputtering working gas, such as Argon, is introduced into the plasma reactor and is maintained at a relatively low pressure by using a series of mass flow controllers and sensors. Subsequently, the direct current (DC) power supply imposes negative electric potential on the target, and the DC voltage between the negatively charged target and the positively charged or grounded shield, which is generally used to protect the plasma reactor (such as a plasma chamber) from being deposited upon, excites or ignites the sputtering working gas into plasma of positively charged ions in the vicinity of the target. The positively charged ions are attracted to a negatively biased metallic target and strike it with sufficient energy to dislodge (sputter) metal atoms from the target, which then coat a wafer positioned in opposition to the target. The sputtering rate is enhanced by positioning a magnet assembly in back of the target which creates an electromagnetic field parallel to the front face of the target. The electromagnetic field traps electrons, which increases the plasma density and hence the sputtering rate.

The continual shrinkage in the feature sizes in order to achieve faster, smaller, and lower power consumption integrated circuits and the constant pursuit of higher yield and better uniformity along the side walls and bottom coverage of the integrated circuit features have resulted in an increasing demand on the uniformity of the deposited materials with higher deposition rate to provide efficient sputtering. One method to increase the ion density, and hence the sputter-deposition rate to improve throughput is to use another electrode that provides more electrons for ionization. Another commonly used method is to use an electromagnetic field to capture and spiral electrons, increasing their ionizing efficiency in the vicinity of the sputtering target. This technique is generally known as a magnetron based sputtering metallization and has found wide applications. In magnetron based sputtering metallization, a magnetron is disposed behind the target to provide efficient sputtering and high deposition rates.

DC magnetron metallization is the most usually practiced commercial form of sputtering. The metallic target is biased to a negative DC bias in the range of about −300 to −700 VDC to attract positive ions of the argon working gas toward the target to sputter the metal atoms. Usually, the sides of the sputter reactor are covered with a shield to protect the chamber walls from sputter deposition. The shield is typically electrically grounded and thus provides an anode in opposition to the target cathode to capacitively couple the DC target power into the chamber and its plasma. General technique for metallization into deep holes ionizes the sputtered atoms and additionally negatively biases the wafer to cause the positively charged sputtered metal atoms to accelerate toward the wafer. Thereby, the sputtering pattern becomes anisotropic and directed toward the bottom of the holes. A negative self-bias naturally develops on an electrically floating pedestal. However, for more control, a voltage may be impressed on the pedestal. Typically, an RF power supply is coupled to a pedestal electrode through a coupling capacitor, and a negative DC self-bias voltage develops on the pedestal adjacent to the plasma.

A magnetron assembly usually comprises opposed magnets of opposing polarity which create an electromagnetic field with the chamber in the neighborhood of the target. Conventional magnetron assemblies usually comprises a rotating or scanning magnetic assembly which produces electromagnetic field in the neighborhood of the sputtering target during the fabrication process. Many conventional magnetron assemblies contain a magnet assembly which further contains a plurality of permanent magnetic pole pieces, each of which is made of the same magnetic material and often has the same magnetic strength. On the other hand, recent development in magnetron sputtering has shown that using an unbalanced magnet assembly in magnetron sputtering has produced better results than using balanced magnet assembly.

Nonetheless, due to various issues with the conventional approaches, it has also been shown that it is difficult to characterize or control the unbalanced nature of such conventional unbalanced magnet assembly due to the fact that these conventional rotating or scanning magnet assemblies comprise permanent magnets, the magnetic strength of which dominates whether the assembled magnet assemblies are unbalanced, and more importantly, how unbalanced these assembled magnet assemblies are. For example, the quality and consistency of the permanent magnetic pole pieces may fluctuate so much that the resulting assembled magnet assembly does not exhibit the intended unbalanced design. In addition, due to complexities of the sputtering environment and the difficulties in accurately simulating or determining whether the magnetron assembly actually meets the unbalanced requirement, the conventional magnetron assemblies cannot be adjusted or modified without disassembling the entire magnetron assembly and replacing the magnetic pole pieces.

For example, if an unbalanced magnetron assembly is designed to generate, by the outer pole pieces, one and a half times magnetic fluxes over the interested surface than the inner pole piece(s), the conventional magnetron assembly, even if it is designed under the guidance of simulation, may not exhibit the desired 1.5 ratio between the outer magnetic pole pieces and the inner pole piece(s). With these conventional designs, the only way to adjust the unbalance ratio is to disassemble the magnetron assembly, remove the inner pole piece(s), the outer pole piece(s), or both, replace the removed pole piece(s) with different pole piece(s), and hope that the modified magnetron assembly would yield the desired unbalanced ratio in the sputtering environment. This is not only cumbersome but also impractical because such a trial-and-error procedure of replacing some pole piece(s) may potentially drag on forever because such magnetron assemblies offer no adjustability for the unbalanced ratio. In addition, removing and replacing magnetic pole pieces has been proven to be a very difficult task and has required the use of special tools due to the strong magnetic strength and the close proximity of these pole pieces.

In addition, conventional sputtering techniques require a DC source to constantly, negatively charge the sputtering target. In order to increase the sputtering yield, there has been a continual demand for a higher output DC power supply, such as a 60 KW DC power supply for a sputtering target, to increase the power density. These high output DC power supplies are not only expensive but also create serious problems due to the excessive amount of heat generated during the sputtering process. Such excessive amount of heat requires that the sputtering target be constantly cooled by, for example, de-ionized water, which not only further increase the cost but also limit the availability of design options of the magnetron assembly as well as of the sputtering chamber.

Therefore, there exists a need for a method and an apparatus for implementing magnetron sputtering techniques.

### SUMMARY OF THE INVENTION

In a single embodiment or in some embodiments, the apparatus for implementing magnetron sputtering for semiconductor fabrication comprises a magnetron assembly. In the single embodiment or in some embodiments, the magnetron assembly comprises a magnet assembly and a driving means for driving the magnet assembly to provide a desired electromagnetic field to cover a sputtering surface of a sputtering target. In the single embodiment or in some embodiments, the magnet assembly comprises one or more inner pieces and one or more of outer pieces such that an electromagnetic field may be established from the inner piece to the outer piece or vice versa under certain operating condition(s). In the single embodiment or in some embodiments, at least one of the one or more inner pieces or the one or more outer pieces of the magnet assembly does not comprise a permanent magnet under certain operating condition(s).

In the single embodiment or in some embodiments, at least one of the one or more inner pieces or the one or more outer pieces of the magnet assembly provides a means for adjust the unbalanced ratio between magnetic fluxes that are generated by the one or more inner pieces and the one or more outer pieces. In the single embodiment or in some embodiments, the apparatus further comprises another magnet assembly to adjust the electromagnetic field during the semiconductor fabrication to improve the electromagnetic field within the neighborhood of a sputtering target. In the single embodiment or in some embodiments, the apparatus may further comprise a DC source, a pulsed DC source, a radio frequency (RF), source, a pulsed DC with RF source, or a DC with RF source to charge the sputtering target during the semiconductor fabrication. Some other embodiments are directed to a method or process of using the apparatus for implementing magnetron sputtering for semiconductor fabrication.

### BRIEF DESCRIPTION OF THE FIGURES

FIG. 1 illustrates an exemplary magnetron sputtering processing apparatus.

FIG. 2 illustrates further details of an exemplary schematic representation of a magnetron assembly and a second magnet assembly relative to a sputtering target.

FIGS. 3A-D illustrate further details of an exemplary schematic representation relative to a sputtering target and some exemplary schematic representations of magnet assemblies of the magnetron assembly.

FIGS. 4A-B illustrate further details of some exemplary schematic representations of the coupled electromagnetic field by the magnetron assembly and the second magnet assembly.

FIG. 5 illustrates further details of an exemplary schematic representation of an exemplary sputtering processing apparatus with further details about the second magnet assembly.

### DETAILED DESCRIPTION OF THE FIGURES

Various embodiments described in the Specification use examples involving a computer software product merely for the ease of explanation or for illustration purposes and do not intend to limit the scope of various embodiments to computer software product only. One of ordinary skills in the art would clearly understand that the written description of various embodiments herein may also be applied to other types of products while achieving identical or substantially similar purposes.

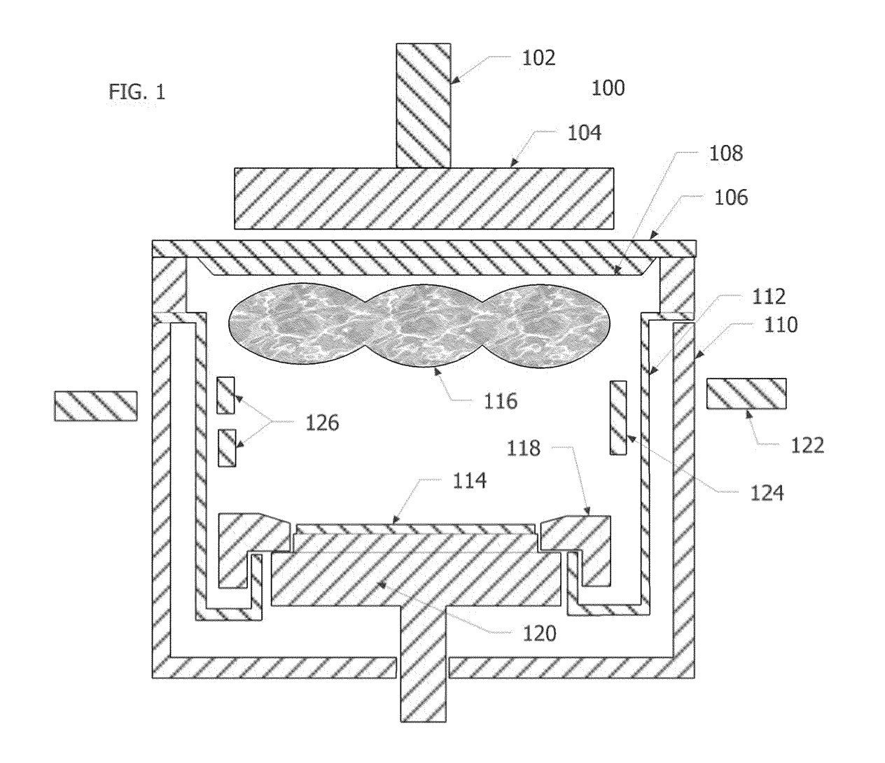

Referring to FIG. 1 which illustrates an exemplary magnetron metallization processing apparatus in a single embodiment or in some embodiments. The processing apparatus comprises a magnetron assembly 100 which comprises a rotating magnetron 104 that is operatively driven by a driving mechanism 102. Further details about the rotating magnetron 104 will be described in further details in subsection paragraphs. The driving mechanism 102 may comprises a motor, such as an electric motor, or any other similar driving or actuation mechanism. The electric motor may comprise an synchronous alternating current (AC) motor, an induction AC motor, a brushed or brushless direct current (DC) motor, an electrostatic motor, a servo motor, a stepper motor, or an internal fan-cooled electric motor. The driving mechanism may be designed to provide sufficient torque and power to drive the magnetron assembly 100 at an angular speed of 10 to 150 revolutions per minute. In various embodiments, the exemplary magnetron metallization processing apparatus are appropriately sized for processing 150 mm, 200 mm, 300 mm, and 450 mm semiconductor substrates.

The exemplary magnetron metallization apparatus may also comprise a sputtering target 108 in the single embodiment or in some embodiments. The sputtering target 108 may be attached to a backing plate 106 by means of, for example, diffusion bonding. The sputtering target 108 may comprise an aluminum target, a titanium (Ti) target, a copper target, Tantalum (Fa), Tungsten (W), Titanium Tungsten (TiW), Nickel (Ni), Cobalt (Co), or any other high purity materials suitable for the metallization process. The purity of the sputtering target is typically six-nines (>99.9999% purity).

The backing plate 106 may be made of various metallic materials that are suitable to attach the sputtering target 108 to and possess sufficiently good heat transfer characteristic such as good thermal conductivity and mechanical strength. In some embodiments, the backing plate 106 comprises a plurality of channels for coolant to pass through, wherein the coolant is provided to maintain the temperature uniformity of the sputtering target. In some embodiments, the coolant comprises de-ionized (DI) water because the sputtering target 108 is electrically charged during the metallization process. In these embodiments, the plurality of channels may be machined into the back side (opposing to the side to which the sputtering target 108 is attached) with adequate cross-sectional profile to ensure sufficient heat exchange without compromising the integrity of the backing plate 106.

For example, the cross-sectional profile of the channel may be designed to ensure that the coolant from a heat exchanger will be circulating through the backing plate at a sufficient flow rate to maintain the temperature of the sputtering target. 108. On the other hand, the cross-sectional profile of the channel is designed in a way by selecting the optimal thickness for the backing plate 106 and optimal depth of the channel because if the structural integrity of the target and the heat transfer efficiency of the backing plate will be compromised if the depth of the channel is made too deep where the sputtering target backing plate assembly may deform and hence adversely affect the metallization process uniformity. The plurality of coolant channels are then sealed off to prevent the coolant from leaking out of the plurality channels.

In some other embodiments, the back side of the backing plate comprises a substantially flat surface with no channels embedded within. In these embodiments, the coolant may be circulating on the back side of the backing plate 106 and conducts heat away from the sputtering target 108 through the backing plate 106. In these embodiments, the rotating magnetron 104 will be submerged in the coolant, and the backing plate is designed to ensure that the sputtering target 108 remains substantially flat throughout the life of the sputtering target 108, and that the backing plate 106 possesses sufficiently good heat transfer characteristics to carry the heat away from the sputtering target 108 during the metallization process.

In the single embodiment or in some embodiments, the exemplary magnetron sputtering apparatus may further comprise a reactor 110 within which the metallization process occur, a pedestal 120 such as an electrostatic chuck or a vacuum chuck on which the semiconductor substrate 114 sits, one or more pieces of grounded, floating, or biased shield 112 which protects the metallization apparatus from undesired deposition of materials from the metallization process, and a covering device 118 to further protect the pedestal 120 from undesired deposition of materials from the metallization process.

In the single embodiment or in some embodiments, the exemplary magnetron metallization apparatus may further comprise a second magnet assembly 122. The second magnet assembly may be positioned relative to the magnetron assembly 100 or relative to the spattering target to improve the electromagnetic field during the metallization process. The second magnet assembly 122 will be described in further details in subsequent paragraphs. In the single embodiment or in some embodiments, the exemplary magnetron metallization apparatus may further comprise one or more RIP components 124 which are electrically connected to one or more single- or multiple-frequency RF power supply with an ISM (Industrial, Scientific, and Medical radio bands) center frequency within a range of 2 MHz to 240 MHz (both inclusive) and an output within a range of 1.25 KW to 120 KW (both inclusive). The one or more RF components 124 are made of substantially the same material as the sputtering target 108 in the single embodiment or in some embodiments because at least a part of the one or more RF components may also be sputtered off and lands on the semiconductor substrate during fabrication in these embodiments. In some embodiments, the one or more RF components 124 may comprise a single, substantially closed loop such as a coil with an opening in the coil to accommodate electrical connections via, for example, electrical feed-throughs. In some embodiments, the one or more RF components 124 may comprise a single, substantially closed loop with a plurality of segments, each of which is electrically connected to the same or different RF sources. In some embodiments, the one or more RF components 124 may comprise multiple substantially closed loops that are arranged vertically at a constant or various spacing, each of which is electrically connected to the same or different RF sources. For example, 126 illustrates two RF components that are vertically arranged at certain spacing. In the single embodiment or in some embodiments, the one or more RF components 124 and 126 are used to control or modify the electromagnetic field that is created by the magnetron assembly 104 and optionally modified by the second magnet assembly 122 so as to obtain a desired electromagnetic field to enhance bottom or sidewall coverage of a feature in the semiconductor device to be fabricated.

During the magnetron metallization process, gas is introduced into the exemplary magnetron metallization apparatus and is subsequently ionized due to the high electric field inside the exemplary magnetron metallization apparatus. The exemplary magnetron metallization apparatus thus ignites and sustains plasma 116 which comprises positively charged ions such as Ar+ which are attracted by the negatively charged sputtering target 108 to start the metallization process for the fabrication of the semiconductor substrate 114.

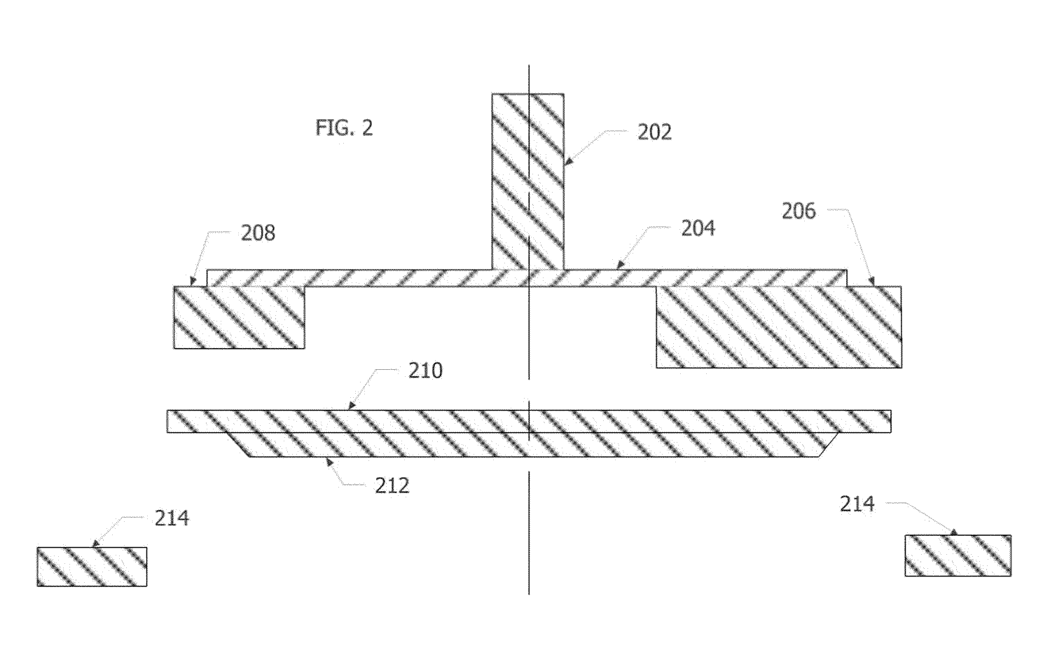

Referring to FIG. 2 which illustrates further details of an exemplary schematic representation of a magnetron assembly and a second magnet assembly relative to a sputtering target in the single embodiment or in some embodiments. It shall be noted that the sputtering target 212, the backing plate 210, and the second magnet assembly 214 are illustrated here in FIG. 2 to illustrate the position of the magnetron assembly relative to the sputtering target 212 and the second magnet assembly 214. If shall be further noted that FIGS. 1-5 are not drawn to scale and thus shall not be so interpreted.

In the single embodiment or in some embodiments, the magnetron assembly comprises a driving mechanism 202 which is similar to the driving mechanism as illustrated in FIG. 1. The magnetron assembly further comprises a magnet assembly 206 which is attached to a linkage arm 204 that is operatively attached to the driving mechanism 202 so as to drive the magnet assembly 206 as designed. The linkage arm 204 also has a counter-weight 208 attached to it to ensure the axis of rotation of the entire magnetron assembly is through the driving shaft of the driving mechanism 202.

In the single embodiment or in some embodiments, the magnet assembly 206 and the linkage arm 204 are designed to cover more than the total area of the sputtering target 212 to improve target utilization. In some embodiments, the magnet assembly 206 and the linkage arm 204 are designed to cover at least 102% of the total area of the sputtering target 212. In some embodiments, the magnet assembly 206 and the linkage arm 204 are designed to cover no greater than 120% of the total area of the sputtering target 212 because increased coverage of the sputtering target area will inherently drive up the cost while the increased gain in target utilization due to the increased coverage remains marginal.

In the single embodiment or in some embodiments, the exemplary magnetron metallization processing apparatus comprises one or more DC power supplies, one or more pulsed power supplies, one or more radio frequency (RF) power supplies, one or more DC with RF power supplies, or one or more pulsed DC with RF power supplies to charge the sputtering target 212 during the semiconductor fabrication process. For example, the exemplary magnetron metallization processing apparatus may comprise one or more DC, pulsed DC, RF, pulsed DC with RF, or DC With RF power supplies for conductive targets and one or more RF power generators for non-conductive targets. In the single embodiment or in some embodiments, the one or more DC or pulsed power supplies are operatively configured to operate at 5%-95% duty cycle with the gas pressure for plasma of 0 milli-torr to 120 milli-torr depending on the types of the metallization process.

In the single embodiment or in some embodiments, the pulsed source such as a pulsed DC source or the pulsed DC with RF source comprises a pulsed DC power supply which provides power within the range of 1.25 KW to 200 KW and produces a plurality of waveforms with one or more frequencies with a range of 0 to 500 KHz and a duty cycle with a range of 5% to 95%. In some embodiments, the pulsed DC power supply comprises a frequency range of 50 to 250 kHz. In some embodiments, the pulsed DC power supply comprises a frequency range of 25 to 125 kHz. In some embodiments, the pulsed DC power supply comprises a pulse width that may be set to a value within 0 to 40% of the duty cycle. In the single embodiment or in some embodiments, the one or more DC or pulsed power supplies are designed or configured to create a power density in a pulse of 50-5000 W/cm² at the sputtering target 212. In the single embodiment or in some embodiments, the one or more DC or pulsed power supplies result in a deposition rate of 0.02-4 μm/min for copper.

In the single embodiment or in some embodiments, the one or more DC or pulsed power supplies are used to reduce electrostatic buildup or to alleviate the thermal budget on the magnetron metallization apparatus by actively duty cycling the one or more pulsed power supplies. In some embodiments, the exemplary magnetron metallization processing apparatus comprises one or more RF power supplies to charge the sputtering target 212 during the fabrication process. In these embodiments, the sputtering target 212 may comprise some insulating materials, such as some oxide material, for which a regular DC power supply or a pulsed power supply is not suitable. In some embodiments, the exemplary magnetron metallization processing apparatus comprises at least one single- or multiple-frequency RF power supply with an ISM (Industrial, Scientific, and Medical radio bands) frequency with a range of 2 MHz to 240 MHz (both inclusive) and an output within at range of 1.25 KW to 100 KW (both inclusive).

In these embodiments, the one or more pulsed power supplies may be configured by using a half-wave rectifier or a full-wave rectifier to produce pulsed DC waveform to charge the sputtering target 212. In the single embodiment or in some embodiments, the one or more pulsed power supplies further comprise at least one capacitor to further smooth the produced pulsed DC waveform by superimposing ripples on a DC waveform. More specifically, the one or more pulsed power supplies charge the at least one capacitor when the pulsed DC voltage is initially applied. The at least one capacitor then functions as a temporary storage device to keep the output pulsed DC waveform at a desired voltage when the pulsed DC waveform is at a low voltage. It shall be noted that although the term pulsed DC waveform is used to describe the generated waveform by the one or more pulsed power supplies, the generated waveform actually exhibits the characteristics of both the alternating current (AC) and the direct current (DC) because the generated waveform (such as a voltage waveform) varies over time while the sign of the generated waveform remains constant.

In the single embodiment or in some embodiments, the exemplary magnetron metallization processing apparatus may further optionally comprise a second magnet assembly 214 that is disposed below the sputtering surface of the sputtering target 212. In these embodiments, the second magnet assembly 214 is used to modify the electromagnetic field within the exemplary magnetron metallization processing apparatus by ensuring that the electromagnetic field in the neighborhood of the sputtering surface of the sputtering target 212 remains substantially parallel to the sputtering surface.

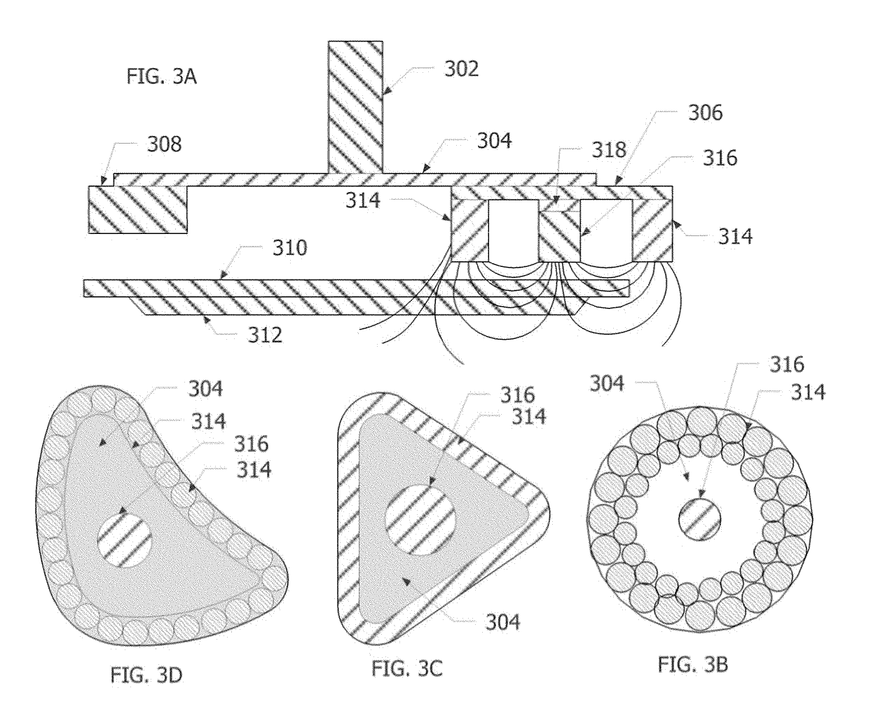

Referring to FIG. 3A-D which illustrate further details of an exemplary schematic representation relative to a sputtering target and some exemplary schematic representations of magnet assemblies of the magnetron assembly. In the single embodiment or in some embodiments, the exemplary magnetron metallization processing apparatus comprises a driving mechanism 302 which is substantially similar to the driving mechanisms 102 and 202 as illustrated in FIGS. 1-2 and described in the preceding paragraphs. The exemplary magnetron metallization processing apparatus further comprises the magnetron assembly which further comprises a linkage arm 304, which is substantially similar to the linkage arm 204. In these embodiments, the magnetron assembly may further comprise a magnet assembly which further comprises a base mounting plate 306 to accommodate the pole pieces 314 and 316.

In the single embodiment or in some embodiments, the base mounting plate 306 is made of some ferromagnetic or ferrous (hereinafter ferrous) material.

In the alternative, the base mounting plate 306 may be made of ferrous, diamagnetic, paramagnetic, or ferromagnetic material. The choice of ferromagnetic materials will be described in further details in subsequent paragraphs. An exemplary diamagnetic material that may be used or the base mounting plate 306 comprises Copper or Lead. An exemplary diamagnetic material that may be used for the base mounting plate 306 comprises magnetite, yttrium iron garnet, or material comprising aluminum, cobalt, nickel, manganese, zinc, and iron oxides. An exemplary paramagnetic material that may be used for the base mounting plate 306 comprises Tungsten, Cesium, Aluminum, Lithium based alloys, or Magnesium based alloys.

In the single embodiment or in some embodiments, the inner pole piece(s) 316 and the outer pole piece(s) 314 are attached to the base mounting plate by any means that are suitable to mount the pole pieces. The assembled base mounting plate 306, the inner pole piece(s), and the outer pole piece(s) are then attached to the linkage arm 304 by any suitable means. The linkage arm 304 is further attached to the driving mechanism 302 so as to be driven as designed. The magnetron assembly may further comprise a counter-balance 308 which is also attached to the linkage arm to ensure the axis of rotation of the magnetron assembly remains substantially coaxial to the axis of rotation of the driving mechanism 302.

In the single embodiment or in some embodiments, the inner pole piece 316 or inner pole pieces (hereinafter inner pole piece) are made of certain material that does not exhibit an magnetic property or strength absent electric energy or electromagnetic field exerted by other magnetic materials. In these embodiments, the inner pole piece 316 is not permanent magnet(s) when it is first manufactured. In some embodiments, the inner pole piece 316 is made of a hard ferrous material. That is, the inner pole piece 316 that is made of a hard ferrous material does not exhibit any electromagnetic field around it when it is first manufactured but becomes magnetized once the inner pole piece 316 is exposed to certain external electromagnetic field. The inner pole piece 316 that is made of hard ferrous material retains at least some of the magnetic strength even after the external electromagnetic field is removed. An exemplary hard ferrous material comprises, for example but not limited to, materials or alloys comprising one or more of Lanthanum, Praseodymium, Neodymium, Cerium, Promethium, Europium, Samarium, Gadolinium, Terbium, Dysprosium, Holmium, Erbium, Ytterbium, or Luteium, or other similar materials. In some embodiments, the ferrous material that may be used for various parts of the exemplary magnetron metallization processing apparatus comprises alloys whose constituents are not ferromagnetic such as Heusler alloys.

In some embodiments, the inner pole piece 316 may comprise a single piece of material of any geometric form with provisions for attaching the inner pole piece 16 to the base mounting plate 306. In some embodiments, the inner pole piece 316 may be encapsulated within a housing which may be made of hard or soft ferrous materials, non-ferrous or non-ferromagnetic materials (hereinafter non-ferrous materials), or a combination of ferrous material and non-ferrous material. For example, in some embodiments where the inner pole piece 316 is of a substantially cylindrical shape (with provisions for attaching to the base mounting plate), the inner pole piece 316 may be encapsulated in a hollow cylindrical casing with end caps on one or both ends. Each of the hollow cylindrical casing and the end caps may be made of hard or soft ferrous or non-ferrous material. The criteria for determining whether the encapsulation or enclosure will be made of hard or soft ferrous or non-ferrous material comprise, for example, the desired magnetic strength of the inner pole piece 316 once the inner pole piece 316 is magnetized. In some embodiments, the use of ferrous materials for the encapsulation or enclosure for the inner pole piece 315 has demonstrated increased magnetic strength or property for the inner pole piece 316 once the inner pole piece 316 is magnetized.

In some other embodiments, the inner pole piece 316 is made of a soft ferrous material. That is, the inner pole piece 316 that is made of a soft ferrous material does not exhibit any magnetic strength when the inner pole piece 316 is first manufactured but becomes magnetized once the inner pole piece 316 is exposed to certain external electromagnetic field. The inner pole piece 316 that is made of a soft ferrous material loses, however, substantially all of its magnetic strength even after the external electromagnetic field is removed.

In these embodiments, the inner pole piece 316 may also comprise a single piece of material of any geometric form with provisions for attaching the inner pole piece 316 to the base mourning plate 306. In some embodiments, the inner pole piece 316 may be encapsulated within a housing which may be made of ferrous materials, non-ferrous materials, or a combination of ferrous material and non-ferrous material. For example, in some embodiments where the inner pole piece 316 is of a substantially cylindrical shape (with provisions for attaching to the base mounting plate), the inner pole piece 316 may be encapsulated in a hollow cylindrical casing with end caps on one or both ends. Each of the hollow cylindrical casing and the end caps may be made of ferrous or non-ferrous material. The criteria for determining whether the encapsulation or enclosure will be made of ferrous or non-ferrous material comprise, for example, the desired magnetic strength of the inner pole piece 316 once the inner pole piece 316 is magnetized. In some embodiments, the use of ferrous materials for the encapsulation or enclosure for the inner pole piece 316 has demonstrated increased magnetic strength or property for the inner pole piece 316 once the inner pole piece 316 is magnetized.

In the single embodiment or in some embodiments where the inner pole piece 316 is made of a ferrous material, the ferrous material may comprise, for example but not limited to, various forms of steel such as mild steel, high speed steel, high tensile steel, high carbon steel, and medium carbon steel, or cast iron.

In the single embodiment or in some embodiments, the inner pole piece 316 may comprise an electromagnet which does not exhibit any magnetic strength absent some form of electric energy. In some embodiments, the inner pole piece 316 is positioned on the base mounting plate 306 such that the magnetic fluxes inside the coil are substantially perpendicular to the base mounting plate 306. In some other embodiments, the inner pole piece 316 is positioned on the base mounting plate 306 such that the magnetic fluxes inside the coil are substantially parallel to the base mounting plate 306.

An exemplary form of the inner pole piece 316 may comprise an electrically conductive coil in some embodiments. The electrically conductive coil may be enclosed within some encapsulation or enclosure which provides connections for the coil to some external source such as a current source. The encapsulation or enclosure may be made of ferrous materials, non-ferrous materials, or a combination of ferrous material and non-ferrous material. In some embodiments, the inner pole piece 316 further comprises an inner element which is made of some ferrous materials to increase the magnetic strength of the inner pole piece 316 at a fixed electric current or to achieve the same magnetic, strength of the inner pole piece 316 at a much lower electric current.

In these embodiments, the inner pole piece 316 may be mounted to the base mounting plate 306 with a spacer element 318 situated between the inner pole piece 316 and the base mounting plate 306. In these embodiments, the spacer element 318 sets the inner pole piece 316 further away from the base mounting plate 306. The spacer element 318 may be of any shape and may comprise one or more empty spaces such as cutouts for the magnetic fluxes to pass through without attenuation in strength. The spacer element 318 may be made of any ferrous or non-ferrous materials or may even be a substantial gap between the inner pole piece 316 and the base mounting plate 306. One of ordinary skill in the art clearly knows that the spacer element is disposed between the base mounting plate 306 and a pole piece and thus may not constitute a complete air gap between the base mounting 306 and the pole piece. Some of the exemplary functions of the spacer element 318 is to adjust or to attenuate the magnetic fluxes going in and out of the inner pole piece 316 so as to adjust the unbalance ratio between the inner pole piece 316 and the outer pole piece 314 or to adjust or modify the electromagnetic field in the vicinity of the sputtering surface of the sputtering target 312 by providing adjustability to the flux density of the magnetic fluxes going into the inner pole piece 316.

For example, the spacer element 318 may provide the adjustability by comprising a adjustment mechanism together with a locking mechanism that may be used to adjust the spacing between the inner pole piece 316 and the base mounting plate 306 and then to lock the inner pole piece 316 in place. An exemplary adjustment mechanism may comprise a simple, small lead screw that is either attached to the inner pole piece 316 or its outer encapsulation or enclosure. An exemplary locking mechanism may comprise as simple as a nut. In some other embodiments, the spacer element may comprise a simple stand-off. In these embodiments, the adjustability may be obtained by simply replacing the stand-off with another stand-off that provides a different spacing between the inner pole piece 316 and the base mounting plate 306.

Some embodiments provide adjustment to the unbalance ratio by varying the thickness of the spacer element 318 or the distance between the pole piece and the base mounting plate 306. Some embodiments provide adjustment to the unbalance ratio by changing the design of the spacer element 318 by, for example, defining one or more apertures in the spacer element 308 for some of the magnetic fluxes to pass through without reduction in strength or density while using the non-cutout portion(s) of the spacer element 308 to reduce the strength of a part of the electromagnetic field or the density of the magnetic fluxes passing the non-cutout portion(s). Some embodiments provide adjustment to the unbalance ratio by using different materials with different magnetic susceptibility or magnetic permeability for the spacer element 318.

In the single embodiment or in some embodiments where the inner pole piece 316 is not a permanent magnet, the outer pole piece or outer pole pieces 314 (hereinafter outer pole piece) comprises permanent magnets or electromagnets. The inner pole piece 316 near the sputtering target 312 is configured to have opposing polarity of the polarity of the end of the outer pole piece 314 near the sputtering target 312. For example, in some embodiments where the end of the inner pole piece 316 near the sputtering target 312 exhibits the south magnetic pole, the end of the outer pole piece 314 near the sputtering target 312 is then configured to exhibit the north magnetic pole.

Alternatively, in some embodiments where the end of the inner pole piece 316 near the sputtering target 312 exhibits the north magnetic pole, the end of the outer pole piece 314 near the sputtering target 312 is then configured to exhibit the south magnetic pole. In some embodiments where electromagnets are used for the inner pole piece 316 or the outer pole piece 314, the poles of such electromagnets or the direction of the current flow through the electromagnets is determined by the right-hand rule.

In the single embodiment or in some embodiments where at least one of the inner pole piece 316 or the outer pole piece 314 does not comprise a permanent magnet, the electromagnetic field is generated by either magnetization or by the application of electric energy. For example, in some embodiments where the inner pole piece 316 does not comprise a permanent magnet and is made of a ferrous material, for example, the inner pole piece 316 is magnetized by the presence of the electromagnetic field created by the outer pole piece 314 once the inner pole piece 316 is assembled in the magnetron assembly.

In these embodiments, the inner pole piece 316 will remain magnetized if the inner pole piece 316 is made of a hard ferrous material and will lose substantially all of its magnetic strength if the inner pole piece is made of a soft ferrous material. As another example, in some embodiments where the inner pole piece 316 comprises an electromagnet, the inner pole piece 316 and the outer pole piece 314 will become magnetically coupled to generate a desired electromagnetic field for fabricating the semiconductor device when some form of electric energy such as a current source is applied to the inner pole piece 316.

The electromagnetic field generated by interaction between the inner pole piece 316 and the outer pole piece 314 is thus schematically represented as shown by the electromagnetic field lines between the pole pieces as illustrated in FIG. 3A. It shall be noted that the electromagnetic field lines between the pole pieces as illustrated in FIG. 3A are purely for illustrative and explanatory purposes and do not exhibit directions of the electromagnetic field because the inner pole piece 316 may be configured to have the north or south magnetic pole around the end near the sputtering target 312, and the outer pole piece 314 may be correspondingly configured.

In some other embodiments, the magnetron assembly may comprise the inner pole piece 316 that comprises a permanent magnet. In these embodiments, the outer pole piece 314 does not comprise a permanent magnet. Rather, the outer pole piece is made of certain material that does not exhibit any magnetic property or strength absent electric energy or electromagnetic field exerted by other magnetic materials. In these embodiments, the inner pole piece 316 comprises a permanent magnet while the outer pole piece 314 does not comprise a permanent magnet.

In some embodiments, the outer pole piece 316 is made of a hard ferrous material. That is, the outer pole piece 316 that is made of a hard ferrous material does not exhibit any electromagnetic field around it when it is first manufactured but becomes magnetized once the outer pole piece 316 is exposed to certain external electromagnetic field. The outer pole piece 316 that is made of a hard ferrous material retains at least some of the magnetic strength even after the external electromagnetic field is removed.

In some other embodiments, the outer pole piece 316 is made of a soft ferrous material. That is, the outer pole piece 316 that is made of a soft ferrous material does not exhibit any magnetic strength when the outer pole piece 316 is first manufactured but becomes magnetized once the outer pole piece 316 is exposed to certain external electromagnetic field. The outer pole piece 316 that is made of a soft ferrous material loses, however, substantially all of its magnetic strength even after the external electromagnetic field is removed.

In the single embodiment or in some embodiments where at least one of the inner pole piece 316 or the outer pole piece 314 does not comprise a permanent magnet, either one of or both of the inner pole piece 316 and the outer pole piece 314 may be attached to a spacer element 318 as discussed above to provide adjustability to the ratio of the unbalance ratio between the inner pole piece 316 and the outer pole piece 314.

In the single embodiment or in some embodiments, both the inner pole piece 316 and the outer pole piece 314 of the magnet assembly of the magnetron assembly may comprise one or more electromagnets whose polarities are properly configured. In these embodiments, the magnet assembly provides further adjustability to the unbalance ratio or the ability to modify the electromagnetic field by vary the en flowing into the inner pole piece 316 and the outer pole piece 314. For example, the magnet assembly may be configured to receive the first amount of current to the inner pole piece 316 and a second amount of current to the outer pole piece 314 to achieve a desired unbalance ratio. In some embodiments, the magnet assembly is configured to achieve an unbalance ratio between 1.02 and 2.5. That is, the integral of the magnetic fluxes generated by the outer pole piece 314 over a surface of interest is configured to exhibit 1.02 to 2.5 times of integral of the magnetic fluxes generated by the inner pole piece 316 over the same surface of interest.

Referring, to FIG. 3B which illustrates a schematic arrangement of the magnet assembly in some embodiments. The magnet assembly as illustrated in FIG. 3B comprises a base mounting plate 304 to which the inner pole piece 316 and a plurality of outer pole piece 314 of the same or different magnetic strengths are attached. The relative magnetic strengths of the inner pole piece 316 and of the outer pole piece 314 may be configured based at least in part upon the desired unbalance ratio or the desired electromagnetic field during the processing of the semiconductor devices. It shall be noted that although FIG. 3B illustrates two rings of outer pole pieces 316, one of ordinary skill in the art clearly knows that the outer pole pieces 316 are not limited to an arrangement of exactly two rings, and that a single ring or more than two rings of outer pole pieces 316 may be used based on the design requirements. In addition, the plurality of outer pole pieces 314 are arranged right next to each other, and the two rings of the outer pole pieces 314 are also arranged right next to each other. Nonetheless, the actual arrangement and the number of the outer pole pieces 314 are determined based at least in part upon the unbalance ratio and/or the desired, electromagnetic field for processing the semiconductor devices.

Referring to FIG. 3C which illustrates a schematic arrangement of the magnet assembly in some embodiments. The magnet assembly as illustrated in FIG. 3B comprises a base mounting plate 304 to which the inner pole piece 316 and a single piece outer pole piece 314 are attached. It shall be noted that although a single outer pole piece 314 is shown in FIG. 3C, the outer pole piece 314 in FIG. 3C may be configured to use multiple individual outer pole pieces of the same or different magnetic strengths, and the arrangement or spacing of these multiple individual outer pole pieces may be determined by the magnetic strength(s) of each of the multiple individual outer pole pieces, the unbalance ratio, or the desired electromagnetic field during the processing of the semiconductor device.

Referring to FIG. 3D which illustrates a schematic arrangement of the magnet assembly in some embodiments. The magnet assembly as illustrated in FIG. 3B comprises a base mounting plate 304 to which the inner pole piece 316 and a single piece or a plurality of outer pole pieces 314 of the same or different magnetic strengths are attached. FIGS. 3B-D respectively illustrate a circular, a substantially triangular, and an irregular magnet assembly. These three configurations are provided here for illustrative and explanatory purposes, and the magnet assembly in various embodiments shall not be limited as such.

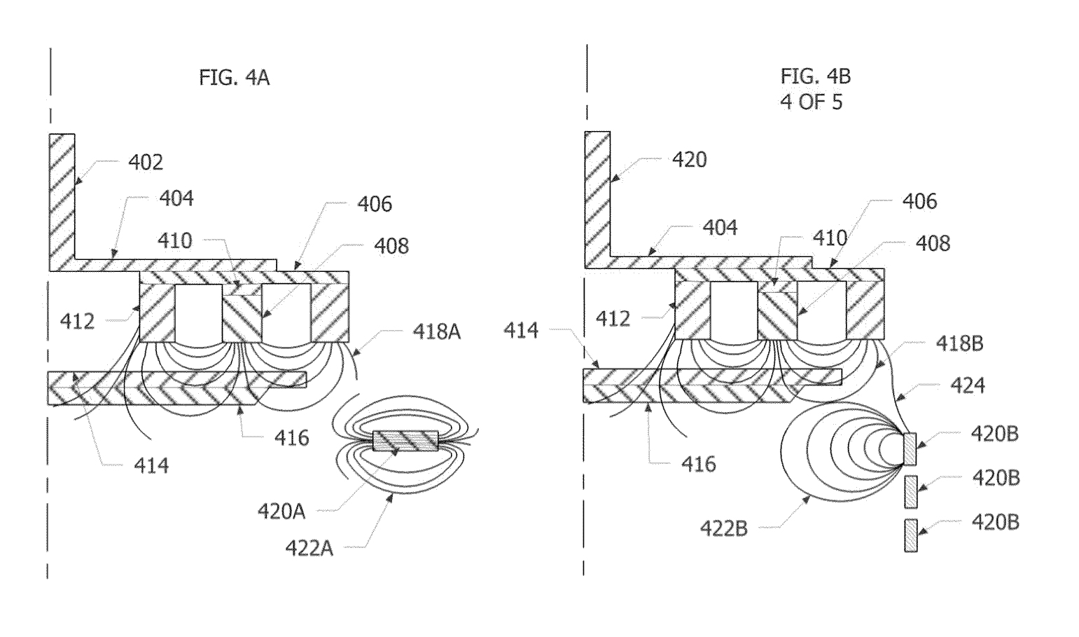

Referring to FIGS. 4A-B which illustrate further details of some exemplary schematic representations of the coupled electromagnetic field by the magnetron assembly and the second magnet assembly. It shall be noted that FIGS. 4A-B only illustrate half of the schematic representations of a part of the magnetron metallization processing apparatus with the center line (the broken line at the left-hand end of FIGS. 4A-B) coincident with the axis of rotation of the magnetron assembly.

FIG. 4A illustrates a schematic representation of the magnetron metallization processing apparatus which comprises a driving mechanism 402 which is substantially similar to the driving mechanism 102, 202, and 302 in FIGS. 1-3 in a single embodiment or in some embodiments. The magnetron assembly further comprises a linkage arm 404, which is substantially similar to the linkage arm 204 and 304 in FIGS. 2-3, and a magnet assembly that is attached to the linkage arm 404. The magnet assembly comprises a base mounting plate 406 to which the inner pole piece 408 and the outer pole piece 412 are attached. In the single embodiment or in some embodiments, a spacer element 410 is disposed between the inner pole piece 408 and the base mounting plate 406 as similarly described with reference to FIG. 3A.

The schematic representation of the electromagnetic field 418A when both the inner pole piece 408 and the outer pole piece 412 are properly charged (e.g., by applying a form of electric energy or by inductive magnetization). The magnet assembly provides adjustability to the unbalance ratio and/or the resulting electromagnetic field 418A by adjusting, for example, the spacer element 410 or the currents into the inner pole piece 408, the outer pole piece 412, or both when electromagnets are used in the single embodiment or in some embodiments. The criterion for determining the desire unbalance ratio or the desired electromagnetic field by using the provisions afforded by the magnetron assembly is to modify the electromagnetic field in a way such that the electromagnetic field lines are substantially parallel to the sputtering surface of the sputtering target 416, which is attached to the backing plate 414 as similar described with reference to FIGS. 1, 2, and 3A. The criterion for determining the desire unbalance ratio or the desired electromagnetic field by using the provisions afforded by the magnetron assembly is to modify the electromagnetic field in a way to achieve higher sputtering yield.

The exemplary magnetron metallization processing apparatus may further comprise a second magnet assembly 420A in the single embodiment or in some embodiments. FIG. 4A illustrates a configuration in which the second magnet assembly 420A is arranged in a way that the magnetic filed lines inside an individual magnet are substantially parallel to the sputtering surface of the sputtering target 416. For example, the second magnet assembly 420A may comprise one or more electromagnets, each of which comprises an electrically conductive coil whose axis is substantially parallel to the sputtering surface of the sputtering target 416. In some embodiments, the second magnet assembly comprises a single piece magnet during the fabrication process. For example, the second magnet assembly may comprise a single, machined piece of permanent magnet.

In the single embodiment or in some embodiments, the second magnet assembly 420A comprises a plurality of individual magnet (either permanent magnet or electromagnet) that are arranged on a virtual plane that is substantially parallel to the sputtering surface of the sputtering target 416. One of ordinary skill in the art clearly knows that although the plurality of individual magnets are designed to be arranged on a virtual plane that is intended to be perfectly parallel to the sputtering surface of the sputtering target 416, the actual arrangement may somehow deviate from such perfect parallelism due to various factors such as tolerances in the manufacturing or installation of the individual magnets and thus may only achieve substantial parallelism. In some embodiments, the magnetron metallization processing apparatus may comprise a plurality of such arrangements on several virtual planes, each of which is substantially parallel to the sputtering surface of the sputtering target 416.

The second magnet assembly 420A is arranged at a level below the sputtering surface of the sputtering target 416 and is used to improve the electromagnetic field or to increase the magnetic flux density in the vicinity of the sputtering surface of the sputtering target 416 by modifying the electromagnetic field generated by the magnetron assembly with the electromagnetic field generated by the second magnetic assembly 420A. In some embodiments, the virtual plane or the first virtual plane of the second magnet assembly 420A is arranged 0.4 in to 13.6 in below the sputtering surface of the sputtering target 416 depending on various criteria which may comprises, for example, the target to substrate spacing, the power applied to the target, the sputtering yield requirement, the desired power density, the shape of the sputtering target 416, etc.

FIG. 4B illustrates another schematic representation of the magnetron metallization processing apparatus which comprises a driving mechanism 402 which is substantially similar to the driving mechanism 102, 202, and 302 in FIGS. 1-3 in a single embodiment or in some embodiments. The magnetron assembly further comprises a linkage arm 404, which is substantially similar to the linkage arm 204 and 304 in FIGS. 2-3, and a magnet assembly that is attached to the linkage arm 404. The magnet assembly comprises a base mounting plate 406 to which the inner pole piece 408 and the outer pole piece 412 are attached. In the single embodiment or in some embodiments, a spacer element 410 is disposed between the inner pole piece 408 and the base mounting plate 406 as similarly described with reference to FIG. 3A.

The schematic representation of the electromagnetic field 418A when both the inner pole piece 408 and the outer pole piece 412 are properly charged (e.g., by applying a form of electric energy or by inductive magnetization). The magnet assembly provides adjustability to the unbalance ratio and/or the resulting electromagnetic field 418B by adjusting, for example, the spacer element 410 or the currents into the inner pole piece 408, the outer pole piece 412, or both when electromagnets are used in the single embodiment or in some embodiments. The criterion for determining the desire unbalance ratio or the desired electromagnetic field by using the provisions afforded by the magnetron assembly is to modify the electromagnetic field in a way such that the electromagnetic field lines are substantially parallel to the sputtering surface of the sputtering target 416, which is attached to the backing plate 414 as similar described with reference to FIGS. 1, 2, and 1A. The criterion for determining the desire unbalance ratio or the desired electromagnetic field by using the provisions afforded by the magnetron assembly is to modify the electromagnetic field in a way to achieve higher sputtering yield.

The exemplary magnetron metallization processing apparatus may further comprise a second magnet assembly 420B in the single embodiment or in some embodiments. FIG. 4B illustrates a configuration in which the second magnet assembly 420B is arranged in a way that the magnetic filed lines inside an individual magnet are substantially perpendicular to the sputtering surface of the sputtering target 416. For example, the second magnet assembly 420B may comprise one or more electromagnets, each of which comprises an electrically conductive coil whose axis is substantially perpendicular to the sputtering surface of the sputtering target 416.

In the single embodiment or in some embodiments, the second magnet assembly 420B comprises a plurality of individual magnet (either permanent magnet or electromagnet) that are arranged on a virtual plane that is substantially parallel to the sputtering surface of the sputtering target 416. In the configuration as illustrated in FIG. 4B three sets of magnets 420B are arranged on three separate planes, each of which is substantially parallel to the sputtering surface of the sputtering target 416. One of ordinary skill in the art clearly knows that although the plurality of individual magnets are designed to be arranged on a virtual plane that is intended to be perfectly parallel to the sputtering surface of the sputtering target 416, the actual arrangement may somehow deviate from such perfect parallelism due to various factors such as tolerances in the manufacturing or installation of the individual magnets and thus may only achieve substantial parallelism. In some embodiments, the magnetron metallization processing apparatus may comprise a plurality of such arrangements on several virtual planes, each of which is substantially parallel to the sputtering surface of the sputtering target 416.

The virtual plane (of there exists only one set of magnets for the second magnet assembly 420B) or the first virtual plane (if there exists more than one set of magnets) of the second magnet assembly 420B is arranged at a level above or below the sputtering surface of the sputtering target 416 and is used to improve the electromagnetic field or to increase the magnetic flux density in the vicinity of the sputtering surface of the sputtering target 416 by modifying the electromagnetic field generated by the magnetron assembly with the electromagnetic field generated by the second magnetic assembly 420B. The positioning of the second magnet assembly 420B may also be used to develop the desired magnetic filed during the metallization process by placing the second magnet assembly 420A at a position such that the resulting electromagnetic field is substantially parallel to the sputtering surface of the sputtering target 416 in some embodiments. In these embodiments, the magnetron assembly may be configured to cover a total area that is less that total area of the target due to the aid of the second magnet assembly 420B.

In some embodiments, the virtual plane or the first virtual plane of the second magnet assembly 420A is arranged no more than 6.5 inches above the sputtering surface of the sputtering target 416 or 0.4 in to 13.6 in below the sputtering surface of the sputtering target 416 depending on various criteria which may comprises, for example, the target to substrate spacing, the power applied to the target, the sputtering yield requirement, the desired power density, the shape of the sputtering target 416 the actual configuration of the magnetron assembly, etc.

In the single embodiment or in some embodiments, the second magnet assembly may comprise a combination of the configurations 420A and 420B. That is, in these embodiments, the second magnet assembly may comprise one or more magnets that are arranged “horizontally” as 420A in FIG. 4A and one or more magnets that are arranged “vertically” as 420B in FIG. 4B, in some embodiments, one or more pole pieces of the second magnet assembly may be positioned relative to the sputtering surface of the sputtering target 416 such that the electromagnetic field within the one or more pole pieces of the second magnet assembly is at an angle that is neither substantially parallel nor substantially perpendicular to the sputtering surface of the sputtering target 416. It shall be noted that the electromagnetic field lines with a magnet still exhibit certain curvatures although macroscopically these electromagnetic field lines runs in a substantially the same direction and are thus deemed substantially parallel to that direction.

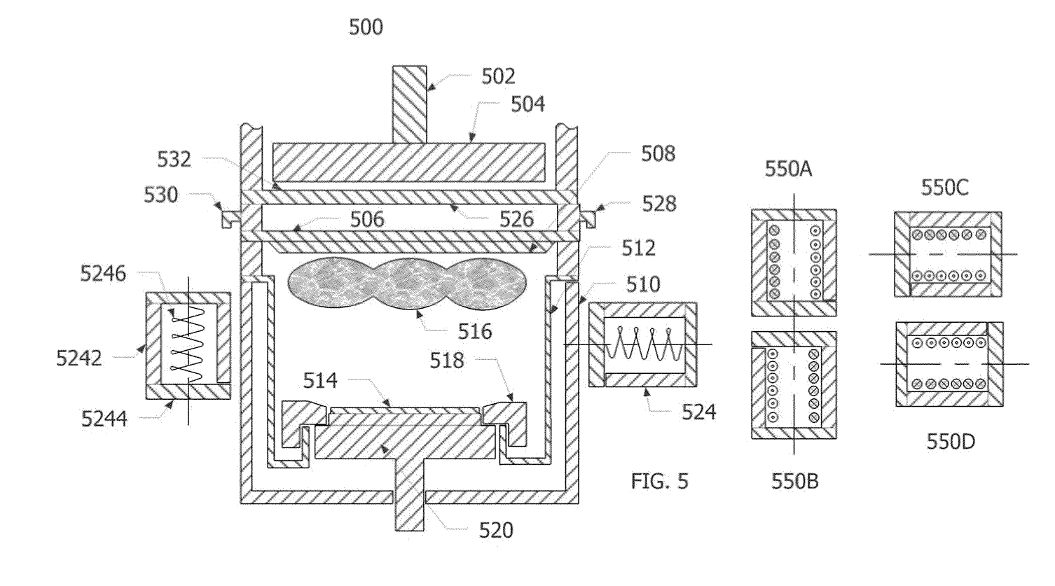

Referring to FIG. 5 which illustrates further details of an exemplary schematic representation of an exemplary metallization processing apparatus with further details about the second magnet assembly. In the single embodiment or in some embodiments, the exemplary metallization processing, apparatus 500 comprises a magnetron a driving mechanism 502, which is similar to 102, 202, 302, and 402 with reference to FIGS. 1-4, and a magnetron assembly 504 as described above. Note that the magnetron assembly 504 is symbolically represented as a block for simplicity. The exemplary metallization processing; apparatus 500 may further comprise a sputtering target 508 that is attached to a backing plate 506 by, for example, diffusion bonding.

The exemplary metallization processing, apparatus 500 may further comprise a shield 512, a reactor chamber body 510, a pedestal 520, and a pedestal covering device 518, where the pedestal covering device 518 and the shield 510 are intended to protect against undesired sputtering or deposition of materials in undesired areas inside the reactor chamber body 510. In addition, the shield may be floating, grounded, or biased depending upon the requirements of the fabrication process or the semiconductor device. During the fabrication process, the target is charged by one or more power supplies, such as the pulsed power supply as described above, and some gas is introduced into the reactor chamber body 510. Plasma 516 is ignited and sustained during the fabrication process to cause sputtering from the sputtering target 508 to occur.

The exemplary metallization processing apparatus 500 may further comprise the second magnet assembly 524. FIG. 5 illustrates the use of electromagnets for the second magnet assembly 524. Nonetheless, the second magnet assembly 524 is not limited to only electromagnets. Furthermore, the horizontal and vertical arrangement of the electromagnets is illustrated in FIG. 5. Nonetheless, each of the individual magnets of the second magnet assembly 524 may be arranged at any angle relative to the target surface in order to achieve the desired electromagnetic field.

In addition, the electromagnets are shown to comprise a coil which may be enclosed within an encapsulation or enclosure that comprises the hollow casing 5242 and two end caps 5244 and 5246. Each of the hollow casing 5242 and the two end caps 5244 and 5246 may be made of ferrous material or non-ferrous material. Moreover, one or more of the electromagnets may comprise a ferrous element (not shown) that is wrapped by the electrically conductive coil to further increase the magnetic, strength of the electromagnets, 550A-B illustrate that the second magnet assembly 524 in a vertical orientation (relative to the sputtering target 508) may comprise multiple sets of magnets where each set is located on a virtual plane that is substantially parallel to the sputtering surface of the sputtering target 508. 550C-D illustrate that, the second magnet assembly 524 in a horizontal orientation (relative to the sputtering target 508) may comprise multiple sets of magnets where each set is located on a virtual plane that is substantially parallel to the sputtering surface of the sputtering target 508.

In the single embodiment or in some embodiments, the exemplary metallization processing apparatus 500 may further comprise a plenum that is situated immediately above the sputtering target 508 and is confined by a divider element 526 which isolates the plenum from the magnetron assembly that comprises the driving mechanism 502 and the magnetron assembly 504. In these embodiments, the plenum used to contain coolant which provides cooling to the sputtering target 508. In these embodiment, the coolant supplied by a heat exchanger at a desired flow rate goes through a series of mass flow controllers and enters the plenum via 528 and exists the plenum via 530 to provide carry away the heat generated by the applied power and the bombardment from the metallization process. In these embodiments, the divider element 526 provides sufficient isolation of the magnetron assembly from the coolant.

In the foregoing specification, the invention has been described with reference to specific embodiments thereof. It will, however, be evident that various modifications and changes may be made thereto without departing from the broader spirit and scope of the invention. For example, the above-described process flows are described with reference to a particular ordering of process actions. However, the ordering of many of the described process actions may be changed without affecting the scope or operation of the invention. The specification and drawings are, accordingly, to be regarded in an illustrative rather than restrictive sense. Moreover, unless otherwise explicitly stated, various processes need not be performed in order to achieve the intended purpose(s) in the order as they are described in the foregoing specification. Similarly, unless otherwise explicitly stated, various modules or parts of the system need not be invoked in the order they are described in the foregoing specification in order to achieve the intended purpose(s).

1. A magnetron apparatus for processing of a semiconductor device, comprising:
a driving mechanism;
a magnet assembly which is operatively coupled to the driving mechanism and comprises:
one or more inner pole pieces attached to a base mounting plate; and
one or more outer pole pieces, wherein
the magnet assembly creates a electromagnetic field that is used for the processing of the semiconductor device, wherein at least pole piece of the one of the inner pole piece and the one or more outer pole pieces is not a permanent magnet; and
a counter balance that is configured based at least on the magnetron assembly.

2. The magnetron apparatus of claim 1, wherein the at least one pole piece comprises an electromagnet.

3. The magnetron apparatus of claim 2, wherein the electromagnet comprises a ferrous element that is substantially enclosed by the electromagnet.

4. The magnetron apparatus of claim 2, wherein the electromagnet comprises an enclosure that is made of a combination of ferrous and non-ferrous material.

5. The magnetron apparatus of claim 1, wherein the at least one pole piece comprises a hard ferrous material which does not exhibit magnetic strength before the at least one pole piece is assembled in the magnetic assembly.

6. The magnetron apparatus of claim 1, wherein the at least one pole piece comprises a soft ferrous material which does not exhibit magnetic strength before the at least one pole piece is assembled in the magnetron assembly.

7. The magnetron apparatus of claim 1, wherein the one or more inner pole pieces do not comprise a permanent magnet, and the one or more outer pole pieces comprises one or more permanent magnets.

8. The magnetron apparatus of claim 1, wherein both the one or more inner pole pieces and the one or more outer pole pieces comprise only electromagnets.

9. The magnetron apparatus of claim 8, wherein an electromagnetic field within at least one of the electromagnets is substantially parallel to a sputtering target.

10. The magnetron apparatus of claim 1, wherein the one or more inner pole pieces comprise one or more permanent magnets, and the one or more outer pole pieces do not comprise a permanent magnet.

11. The magnetron apparatus of claim 1, wherein a second electromagnetic field within at least one of the electromagnets is positioned substantially parallel or substantially perpendicular to a sputtering surface of a sputtering target

12. The magnetron apparatus of claim 1, wherein a second electromagnetic field within at least one of the electromagnets is positioned at an angle that is neither substantially parallel nor substantially perpendicular to a sputtering surface of a sputtering target.

13. The magnetron apparatus of claim 1, further comprising:
means for adjusting a characteristic of an electromagnetic field created by the magnet assembly for the processing of the semiconductor device.

14. The magnetron apparatus of claim 1, wherein the characteristic comprises an unbalance ratio between magnetic fluxes created by one or more inner pole pieces and magnetic fluxes created by one or more outer pole pieces, a electromagnetic field distribution near a sputtering surface of the sputtering target, sputtering yield of a sputtering target for the processing of the semiconductor device, or a power density on a sputtering surface of the sputtering target.

15. The magnetron apparatus of claim 1, further comprising a spacer element situated between the at least one pole piece and the base mounting plate, wherein the spacer element comprises a ferrous material or non ferrous materials or a substantial gap.

16. A magnetron based metallization apparatus for processing of a semiconductor device, comprising
a magnetron assembly which is operatively coupled to the driving mechanism to exhibit rotational motion and is located atop a sputtering target, wherein
the magnetron assembly comprises at least one pole piece that is not a permanent magnet; and
a second magnet assembly which comprises one or more pole pieces, wherein
the second magnet assembly is located on one or more sides of the sputtering target, and
the second magnet assembly is configured to modify a characteristic of an electromagnetic field created by the magnetron assembly for the processing of the semiconductor device based on one or more criteria.

17. The magnetron based metallization apparatus of claim 16, further comprising:
a plenum that accommodates cooling means for the sputtering target, wherein
the plenum is separated from the magnetron assembly.

18. The magnetron based metallization apparatus of claim 16, wherein a first magnetic field within at least one of the one or more pole pieces is at an angle that is neither substantially parallel nor substantially perpendicular to a normal direction of a sputtering surface of the sputtering target.

19. The magnetron based metallization apparatus of claim 16, wherein a second magnetic field within at least one of the one or more pole pieces of the second magnet assembly is substantially parallel to a sputtering surface of the sputtering target.

20. The magnetron based metallization apparatus of claim 16, wherein a second magnetic field within at least one of the one or more pole pieces of the second magnet assembly is substantially perpendicular to a sputtering surface of the sputtering target.

21. The magnetron based metallization apparatus of claim 16, wherein the second magnet assembly comprises at least one of an electromagnet, a permanent, and a component that comprises hard or soft ferrous material.

22. The magnetron based metallization apparatus of claim 16, wherein the characteristic comprises an unbalance ratio between magnetic fluxes created by one or more inner pole pieces and magnetic fluxes created by one or more outer pole pieces, an electromagnetic field distribution near a sputtering surface of the sputtering target, sputtering yield of a sputtering target for the processing of the semiconductor device, or a power density on as sputtering surface of the sputtering target.

23. The magnetron based sputtering metallization processing apparatus of claim 16, wherein the sputtering target is charged by one or more DC, RF, or pulsed power supplies.
